(19) United States
(12) Patent Application Publication
(10) Pub. No.: US 2008/0297498 A1
(43) Pub. Date: Dec. 4, 2008

(54) LIGHT-SOURCE DRIVING DEVICE AND ITS SIGNAL TRANSFORMING CIRCUIT AND PULSE GENERATING CIRCUIT

(76) Inventors: Tai-Sheng PO, Taoyuan Hsien (TW); Qiang Ding, Taoyuan Hsien (TW)

Correspondence Address: BIRCH STEWART KOLASCH & BIRCH, PO BOX 747, FALLS CHURCH, VA, 22040-0747, US

(21) Appl. No.: 12/028,655

(22) Filed: Feb. 8, 2008

(30) Foreign Application Priority Data
May 31, 2007 (TW) 096119489

(51) Int. Cl. G09G 5/00; H03K 3/017

(52) U.S. Cl. 345/208; 327/175

(57) ABSTRACT

A light-source driving device includes a pulse controlling circuit, a signal adjusting circuit and a driving circuit. The pulse controlling circuit generates a first controlling signal and a second controlling signal. The signal adjusting circuit is coupled to the pulse controlling circuit and outputs a first switching signal, a second switching signal, a third switching signal and a fourth switching signal according to the first controlling signal and the second controlling signal, respectively. The driving circuit is coupled to the signal adjusting circuit and at least one light-emitting unit, and generates a driving signal to drive the light-emitting unit according to the first switching signal, the second switching signal, the third switching signal and the fourth switching signal.

### CROSS REFERENCE TO RELATED APPLICATIONS

This Non-provisional application claims priority under 35 U.S.C. §119(a) on Patent Application No(s). 096119489 filed in Taiwan, Republic of China on May 31, 2007, the entire contents of which are hereby incorporated by reference.

### BACKGROUND OF THE INVENTION

1. Field of Invention

The invention relates to a light-source driving device and its signal transforming circuit and pulse controlling circuit.

2. Related Art

Compared with a conventional cathode ray tube (CRT) display, a liquid crystal display (LCD) has the advantages of smaller size, lower power consumption and lower radiation, and has the manufacturing technology compatible with the semiconductor manufacturing technology. Thus, the LCD gradually replaces the CRT display and becomes the mainstream of the display.

The LCD is a non-self-emissive display, and an external light source is needed to provide the light for a displayed frame. In general, the LCD includes a backlight module for providing uniform light for a display panel. In addition, a cold cathode fluorescent lamp (CCFL) has the advantages of long lifetime, high brightness and small tube diameter so that the CCFL is widely applied to the backlight module.

In the prior art, a half-bridge driving circuit and a full-bridge driving circuit are often utilized to drive the CCFL of the backlight module. The half-bridge driving circuit and the full-bridge driving circuit control a voltage and a current of the CCFL by modulating the turn-on phase of a transistor and thus adjust the brightness of the CCFL. In practice, the half-bridge driving circuit only needs two sets of controlling signals to generate the desired driving signal, while the full-bridge driving circuit needs four sets of controlling signals to generate the desired driving signal. However, the full-bridge driving circuit can provide higher power to drive the load electrically connected thereto.

The architecture of the full-bridge driving circuit will be described in the following. Referring to FIG. 1, a conventional full-bridge driving circuit 1 includes a full-bridge architecture unit 11, an isolation transforming unit 13 and a controlling unit 12. The full-bridge architecture unit 11 includes four transistors Q01 to Q04. The controlling unit 12 outputs four controlling signals to respectively control the transistors Q01 to Q04 to turn on or off, and transmits a power signal to the isolation transforming unit 13 according to on/off states of the transistors Q01 to Q04. The isolation transforming unit 13 transforms the power signal into a driving signal to drive the CCFL L electrically connected thereto.

As mentioned hereinabove, the half-bridge driving circuit only has two transistors, and the controlling unit only has to output two sets of controlling signals to drive the load. Although the half-bridge driving circuit has simpler circuit construction, its driving ability is poorer than that of the full-bridge driving circuit. Therefore, it is an important subject to provide a light-source driving device with the advantage of the half-bridge driving circuit and also having better driving ability as the full-bridge driving circuit.

### SUMMARY OF THE INVENTION

In view of the foregoing, an object of the invention is to provide a light-source driving device with a simplified controlling method, and its signal transforming circuit and pulse controlling circuit.

To achieve the above, the invention discloses a light-source driving device including a pulse controlling circuit, a signal adjusting circuit and a driving circuit. The pulse controlling circuit generates a first controlling signal and a second controlling signal. The signal adjusting circuit is coupled to the pulse controlling circuit and respectively outputs a first switching signal, a second switching signal, a third switching signal and a fourth switching signal according to the first and second controlling signals. The driving circuit is coupled to the signal adjusting circuit and at least one light-emitting unit, and generates a driving signal to drive the light-emitting unit according to the first, second, third and fourth switching signals.

To achieve the above, the invention also discloses a pulse controlling circuit including a programmable frequency generating unit, a comparing unit, a feedback controlling unit and a pulse generating unit. The programmable frequency generating unit generates a pulse width modulation (PWM) signal. The comparing unit is coupled to the programmable frequency generating unit and generates a first comparing signal and a second comparing signal according to the PWM signal and a reference signal. The feedback controlling unit receives a feedback signal. The pulse generating unit is coupled to the comparing unit and the feedback controlling unit, and respectively outputs a first controlling signal and a second controlling signal according to the feedback signal, the first comparing signal and the second comparing signal.

In addition, the invention further discloses a signal transforming circuit including a signal adjusting circuit and a driving circuit. The signal adjusting circuit receives a first controlling signal and a second controlling signal and outputs a first switching signal, a second switching signal, a third switching signal and a fourth switching signal, respectively. The driving circuit is coupled to the signal adjusting circuit and generates a driving signal according to the first, second, third and fourth switching signals.

As mentioned above, the light-source driving device and its signal transforming circuit and pulse controlling circuit according to the invention have the following features. In detail, the signal adjusting circuit transforms the first controlling signal and the second controlling signal into the first switching signal, the second switching signal, the third switching signal and the fourth switching signal to drive the transistors contained in the driving circuit. Thus, the invention provides an easier controlling method to drive the light-source driving device and its signal transforming circuit, pulse controlling circuit and light-emitting unit under the precondition without decreasing the driving ability.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic illustration showing a conventional full-bridge driving circuit;

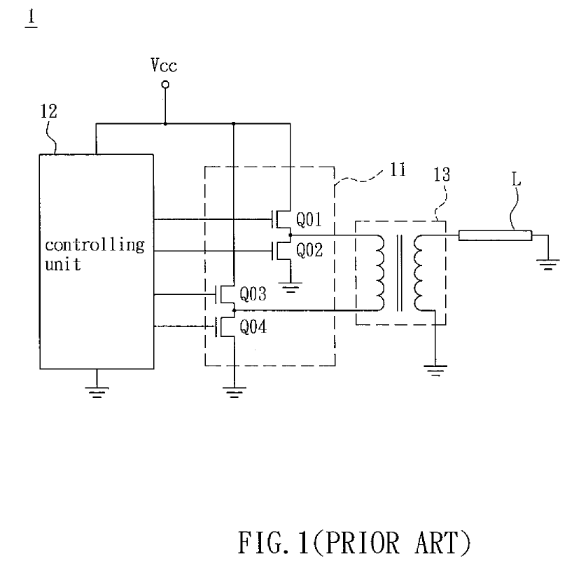

FIG. 2 is a schematic illustration showing a light-source driving device according to a preferred embodiment of the invention;

FIG. 3 is a schematic illustration showing a pulse controlling circuit according to FIG. 2; and

FIG. 4 is a schematic illustration showing output waveforms of the pulse controlling circuit and a switching unit.

### DETAILED DESCRIPTION OF THE INVENTION

The present invention will be apparent from the following detailed description, which proceeds with reference to the accompanying drawings, wherein the same references relate to the same elements.

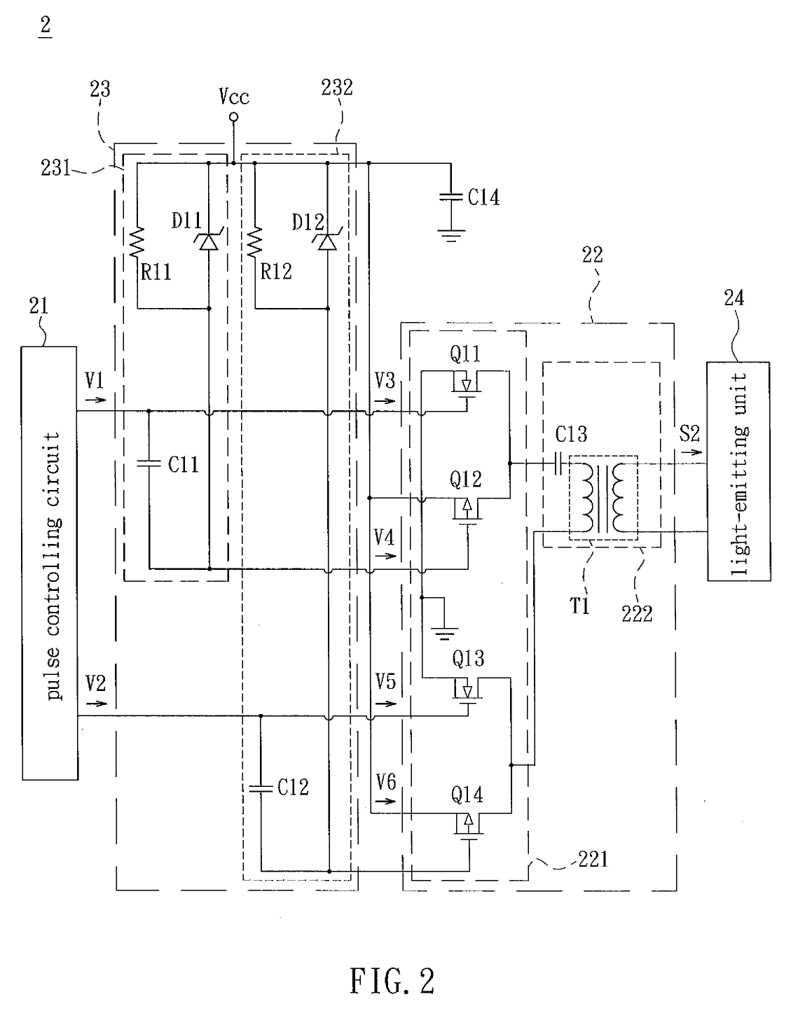

Referring to FIG. 2, a light-source driving device 2 according to a preferred embodiment of the invention includes a pulse controlling circuit 21, a signal adjusting circuit 23 and a driving circuit 22. The signal adjusting circuit 23 is disposed between and electrically connected to and between the driving circuit 22 and the pulse controlling circuit 21. In addition, the signal adjusting circuit 23 and the driving circuit 22 can be integrated as a signal transforming circuit.

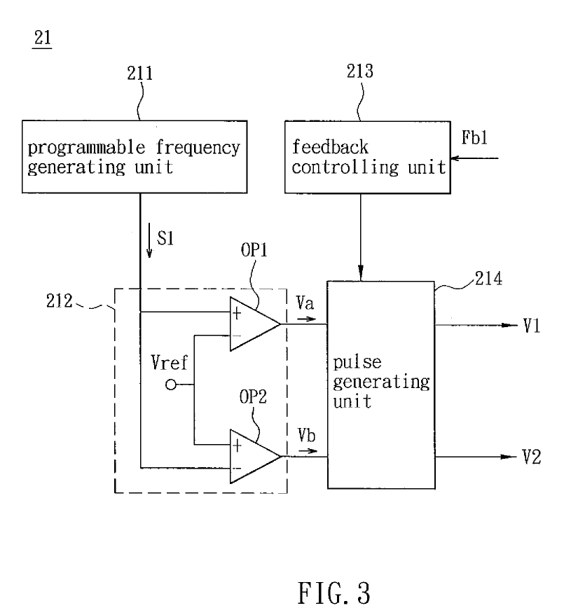

With reference to FIG. 3, the pulse controlling circuit 21 will be described herein below. The pulse controlling circuit 21 includes a programmable frequency generating unit 211, a comparing unit 212, a feedback controlling unit 213 and a pulse generating unit 214. The pulse generating unit 214 is coupled to the feedback controlling unit 213 and the comparing unit 212, and the comparing unit 212 is coupled to the programmable frequency generating unit 211.

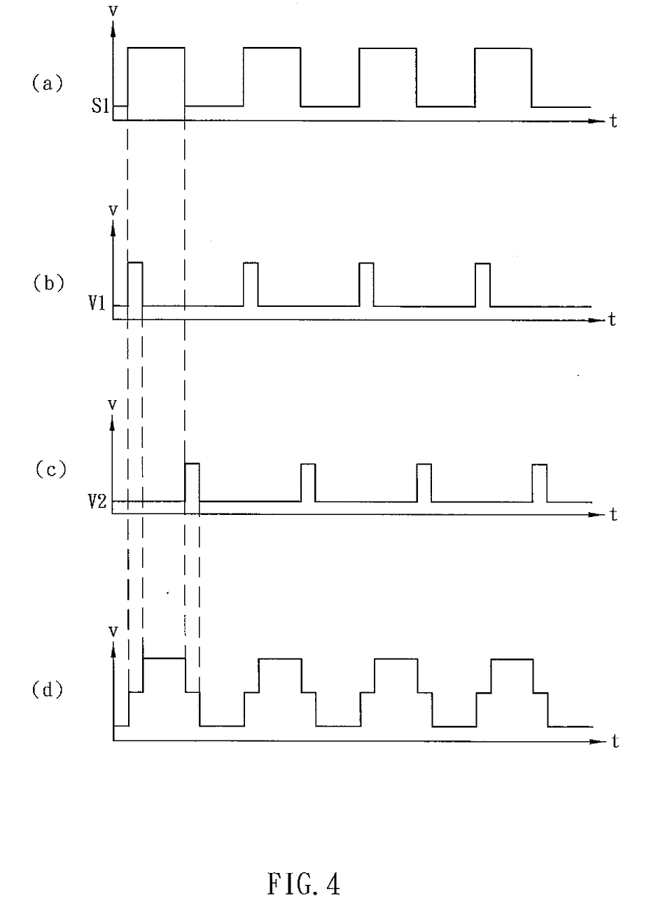

The programmable frequency generating unit 211 generates a pulse width modulation (PWM) signal S1 and transmits the PWM signal S1 to the comparing unit 212. The PWM signal S1, as shown in FIG. 4(a), has a duty cycle equal to, for example, 50%. Of course, in a different aspect, the duty cycle thereof can be adjusted arbitrarily according to the requirement. It is to be noted that the PWM signal S1 can be a programmable constant-frequency output.

The comparing unit 212 includes a first comparator OP1 and a second comparator OP2. The first comparator OP1 has a positive input terminal for receiving the PWM signal S1, and a negative input terminal for receiving a reference signal Vref. The first comparator OP1 has an output terminal for outputting a first comparing signal Va according to the PWM signal S1 and the reference signal Vref, and transmitting the first comparing signal Va to the pulse generating unit 214.

The second comparator OP2 has a positive input terminal for receiving the reference signal Vref, and a negative input terminal for receiving the PWM signal S1. The second comparator OP2 has an output terminal for outputting a second comparing signal Vb according to the reference signal Vref and the PWM signal S1, and transmitting the second comparing signal Vb to the pulse generating unit 214.

In this embodiment, the first comparator OP1 receives the PWM signal S1 from the positive input terminal, and the second comparator OP2 receives the PWM signal S1 from the negative input terminal. Consequently, a phase difference exists between the first comparing signal Va and the second comparing signal Vb. In this embodiment, the phase difference may be equal to 180°.

As shown in FIG. 3, the feedback controlling unit 213 receives at least one feedback signal Fb1 transmitted from the driving circuit 22 or a light-emitting unit 24, and transmits the feedback signal Fb1 to the pulse generating unit 214. In this embodiment, the feedback signal Fb1 may be a voltage signal or a current signal.

The pulse generating unit 214 outputs a first controlling signal V1, as shown in FIG. 4(b), according to the feedback signal Fb1 and the first comparing signal Va. Similarly, the pulse generating unit 214 outputs a second controlling signal V2, as shown in FIG. 4(c), according to the feedback signal Fb1 and the second comparing signal Vb. Because a phase difference exists between the first comparing signal Va and the second comparing signal Vb, a phase difference also exists between the first controlling signal V1 and the second controlling signal V2.

As shown in FIG. 4, if the PWM signal S1 is at the positive rising edge, the first controlling signal V1 has the logic high potential and the second controlling signal V2 has the logic low potential. If the PWM signal S1 is at the negative falling edge, the second controlling signal V2 has the logic high potential and the first controlling signal V1 has the logic low potential. The duty cycle of each of the first controlling signal V1 and the second controlling signal V2 relates to the feedback signal Fb1.

The relationship between the duty cycle of each of the first controlling signal V1 and the second controlling signal V2 and the feedback signal Fb1 will be described in the following. As shown in FIGS. 2 and 3, if the current signal (or voltage signal) transmitted back from the driving circuit 22 or the light-emitting unit 24 is too high, the feedback signal Fb1 is too high. In this case, the duty cycle of the first controlling signal V1 or the second controlling signal V2 can be decreased by the pulse generating unit 214 so that the current signal (or voltage signal) of the driving circuit 22 or the light-emitting unit 24 returns to a predefined value. Correspondingly, if the current signal (or voltage signal) of the driving circuit 22 or the light-emitting unit 24 is too low, the feedback signal Fb1 is too low. In this case, the duty cycle of the first controlling signal V1 or the second controlling signal V2 may be increased by the pulse generating unit 214 so that the current signal (or voltage signal) of the driving circuit 22 or the light-emitting unit 24 returns to the predefined value.

In addition, in order to protect the reliability of the circuit under the consideration of the actual operation of the circuit, a period of buffer time (dead time) is required when switching between the logic high potential and the logic low potential. Therefore, if the duty cycle of the PWM signal is equal to 50%, the duty cycle of each of the first controlling signal V1 and the second controlling signal V2 is smaller than 48% to prevent the light-source driving device 2 from generating the malfunction.

As shown in FIG. 2, the signal adjusting circuit 23 includes a first signal adjusting unit 231 and a second signal adjusting unit 232. The first signal adjusting unit 231 generates a first switching signal V3 and a second switching signal V4 according to the first controlling signal V1. The first signal adjusting unit 231 includes a first Zener diode D11, a first resistor R11 and a first capacitor C11. The first Zener diode D11 has a first terminal coupled to a first voltage, such as a power voltage Vcc, and the first resistor R11 is coupled to two terminals of the first Zener diode D11.

The second signal adjusting unit 232 generates a third switching signal V5 and a fourth switching signal V6 according to the second controlling signal V2. The second signal adjusting unit 232 includes a second Zener diode D12, a second resistor R12 and a second capacitor C12. The second resistor R12 has a first terminal coupled to the first voltage, and the second Zener diode D12 is coupled to two terminals of the second resistor R12.

In this invention, the phase difference between the first switching signal V3 and the third switching signal V5 is equal to 180°, and the phase difference between the second switching signal V4 and the fourth switching signal V6 is equal to 180°.

With reference to FIG. 2, the driving circuit 22 includes a switching unit 221 and a boosting unit 222. The switching unit 221 is coupled to the signal adjusting circuit 23 and the boosting unit 222. The switching unit 221 turns on or off according to the first switching signal V3, the second switching signal V4, the third switching signal V5 and the fourth switching signal V6. In addition, the boosting unit 222 generates a driving signal S2 according to whether the switching unit 221 turns on or off.

The switching unit 221 includes a first transistor Q11, a second transistor Q12, a third transistor Q13 and a fourth transistor Q14. In this embodiment, the first transistor Q11 and the third transistor Q13 are NMOS transistors, while the second transistor Q12 and the fourth transistor Q14 are PMOS transistors.

The first transistor Q11 has a gate for receiving the first switching signal V3, and a source coupled to a second voltage (e.g., a grounding voltage). The second transistor Q12 has a gate for receiving the second switching signal V4, a source coupled to the first voltage, and a drain coupled to a drain of the first transistor Q11.

The third transistor Q13 has a gate for receiving the third switching signal V5, and a source coupled to the second voltage. The fourth transistor Q14 has a gate for receiving the fourth switching signal V6, a source coupled to the first voltage, and a drain coupled to a drain of the third transistor Q13.

In the embodiment, the first Zener diode D11, the first resistor R11 and the first capacitor C11 constitute a level shift circuit for the second transistor Q12. The second Zener diode D12, the second resistor R12 and the second capacitor C12 constitute a level shift circuit for the fourth transistor Q14. The functions of the level shift circuit will be described in the following.

As shown in FIGS. 2 and 4, if the first controlling signal V1 is a positive pulse, the first signal adjusting unit 231 generates the second switching signal V4 with the positive pulses to make the second transistor Q12 turn off. Correspondingly, if the first controlling signal V1 is a negative pulse, the first signal adjusting unit 231 generates the second switching signal V4 with the negative pulses to make the second transistor Q12 turn on.

The first controlling signal V1 makes the first transistor Q11 and the second transistor Q12 have inverse on/off states. That is, when the first transistor Q11 turns on, the second transistor Q12 turns off. According to the above-mentioned description, the switching unit 221 has the output, as shown in FIG. 4(d), and the AC-type driving signal S2 is generated after the signal passes through the boosting unit 222.

In this embodiment, it is necessary to use only one controlling signal to control a set of NMOS transistor and PMOS transistor. Therefore, the invention can simultaneously control two sets of NMOS transistors and PMOS transistors according to two controlling signals.

Referring to FIG. 2, the boosting unit 222 includes a transformer T1. The transformer T1 has a primary winding coupled to the switching unit 221, and a secondary winding coupled to the light-emitting unit 24, and the transformer T1 generates the driving signal S2 to drive the light-emitting unit 24 according to the output of the switching unit 221. In this embodiment, the light-emitting unit 24 is a cold cathode fluorescent lamp (CCFL), for example.

The boosting unit 222 of the invention further includes a third capacitor C13, which is coupled to and between the switching unit 221 and the primary winding of the transformer T1, and functions to steady the current.

In addition, the light-source driving device 2 of the invention further includes a fourth capacitor C14, which is coupled to and between a first terminal and a second voltage of the second Zener diode D12, and is for steadying the driving signal 82 outputted from the boosting unit 222.

In summary, the light-source driving device and its signal transforming circuit and pulse controlling circuit according to the invention have the following features. In detail, the signal adjusting circuit transforms the first controlling signal and the second controlling signal into the first switching signal, the second switching signal, the third switching signal and the fourth switching signal to drive the transistors contained in the driving circuit. Thus, the invention provides an easier controlling method to drive the light-emitting unit under the precondition without decreasing the driving ability so that the cost can be effectively controlled.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light-source driving device comprising:
a pulse controlling circuit for generating a first controlling signal and a second controlling signal;
a signal adjusting circuit coupled to the pulse controlling circuit for respectively outputting a first switching signal, a second switching signal, a third switching signal and a fourth switching signal according to the first controlling signal and the second controlling signal; and
a driving circuit coupled to the signal adjusting circuit and at least one light-emitting unit for generating a driving signal to drive the light-emitting unit according to the first switching signal, the second switching signal, the third switching signal and the fourth switching signal.

2. The light-source driving device according to claim 1, wherein the pulse controlling circuit comprises:
a programmable frequency generating unit for generating a pulse width modulation (PWM) signal;
a comparing unit coupled to the programmable frequency generating unit for generating a first comparing signal and a second comparing signal according to the PWM signal and a reference signal;
a feedback controlling unit for receiving a feedback signal; and
a pulse generating unit coupled to the comparing unit and the feedback controlling unit for respectively outputting the first controlling signal and the second controlling signal according to the feedback signal, the first comparing signal and the second comparing signal.

3. The light-source driving device according to claim 2, wherein the comparing unit comprises:
a first comparator having a positive input terminal coupled to the programmable frequency generating unit, a negative input terminal receiving the reference signal, and an output terminal coupled to the pulse generating unit; and
a second comparator having a positive input terminal receiving the reference signal, a negative input terminal coupled to the programmable frequency generating unit, and an output terminal coupled to the pulse generating unit.

4. The light-source driving device according to claim 2, wherein duty cycles of the first controlling signal and the second controlling signal are smaller than a duty cycle of the PWM signal.

5. The light-source driving device according to claim 2, wherein the feedback signal is a voltage signal or a current signal of the driving circuit or the light-emitting unit.

6. The light-source driving device according to claim 1, wherein a phase difference between the first switching signal and the third switching signal is equal to 180°, and a phase difference between the second switching signal and the fourth switching signal is equal to 180°.

7. The light-source driving device according to claim 1, wherein there is a phase difference between the first controlling signal and the second controlling signal.

8. The light-source driving device according to claim 1, wherein the driving circuit comprises:
a switching unit coupled to the signal adjusting circuit for turning on or off according to the first switching signal, the second switching signal, the third switching signal and the fourth switching signal; and
a boosting unit coupled to the switching unit for generating the driving signal according to whether the switching unit turns on or off.

9. The light-source driving device according to claim 8, wherein the switching unit comprises:
a first transistor having a gate for receiving the first switching signal, and a source/drain coupled to a second voltage;
a second transistor having a gate for receiving the second switching signal, a source/drain coupled to a first voltage, and a drain/source coupled to a drain/source of the first transistor;
a third transistor having a gate for receiving the third switching signal, and a source/drain coupled to the second voltage; and
a fourth transistor having a gate for receiving the fourth switching signal, a source/drain coupled to the first voltage, and a drain/source coupled to a drain/source of the third transistor.

10. The light-source driving device according to claim 9, wherein the first transistor and the third transistor are NMOS transistors, and the second transistor and the fourth transistor are PMOS transistors.

11. The light-source driving device according to claim 8, wherein the boosting unit comprises a transformer having a primary winding coupled to the switching unit and a secondary winding coupled to the light-emitting unit.

12. The light-source driving device according to claim 11, wherein the boosting unit further comprises a first capacitor coupled to and between the switching unit and the primary winding of the transformer.

13. The light-source driving device according to claim 1, wherein the signal adjusting circuit comprises:
a first signal adjusting unit coupled to the pulse controlling circuit for generating the first switching signal and the second switching signal according to the first controlling signal; and
a second signal adjusting unit coupled to the pulse controlling circuit for generating the third switching signal and the fourth switching signal according to the second controlling signal.

14. The light-source driving device according to claim 13, wherein the first signal adjusting unit comprises:
a first Zener diode coupled to a first voltage;
a first resistor coupled to the first Zener diode; and
a second capacitor having a first terminal receiving the first controlling signal, and a second terminal coupled to the first Zener diode and the driving circuit.

15. The light-source driving device according to claim 14, further comprising a fourth capacitor coupled to and between the first Zener diode and a second voltage.

16. The light-source driving device according to claim 13, wherein the second signal adjusting unit comprises:
a second Zener diode coupled to a first voltage;
a second resistor coupled to the second Zener diode; and
a third capacitor having a first terminal receiving the second controlling signal, and a second terminal coupled to the second Zener diode and the driving circuit.

17. The light-source driving device according to claim 1, wherein the light-emitting unit is a cold cathode fluorescent lamp (CCFL).

18. A pulse controlling circuit comprising:
a programmable frequency generating unit for generating a pulse width modulation (PWM) signal;
a comparing unit coupled to the programmable frequency generating unit for generating a first comparing signal and a second comparing signal according to the PWM signal and a reference signal;
a feedback controlling unit for receiving a feedback signal; and
a pulse generating unit coupled to the comparing unit and the feedback controlling unit for respectively outputting a first controlling signal and a second controlling signal according to the feedback signal, the first comparing signal and the second comparing signal.

19. The pulse controlling circuit according to claim 18, wherein the comparing unit comprises:
a first comparator having a positive input terminal coupled to the programmable frequency generating unit, a negative input terminal receiving the reference signal and an output terminal coupled to the pulse generating unit; and
a second comparator having a positive input terminal receiving the reference signal, a negative input terminal coupled to the programmable frequency generating unit and an output terminal coupled to the pulse generating unit.

20. A signal transforming circuit comprising:
a signal adjusting circuit for receiving a first controlling signal and a second controlling signal and outputting a first switching signal, a second switching signal, a third switching signal and a fourth switching signal, respectively; and
a driving circuit coupled to the signal adjusting circuit for generating a driving signal according to the first switching signal, the second switching signal, the third switching signal and the fourth switching signal.
